(19) United States
(12) Patent Application Publication
(10) Pub. No.: US 2012/0129097 A1
(43) Pub. Date: May 24, 2012

(54) Photopolymer Printing Plates with In Situ Non-Directional Floor Formed During Extrusion

(76) Inventors: Jonghan Choi, Smyrna, GA (US); Kerry O'Brate, Decatur, GA (US); Chouaib Boukaftane, Smyrna, GA (US)

(21) Appl. No.: 12/949,095

(22) Filed: Nov. 18, 2010

(51) Int. Cl. G03F 7/004

(52) U.S. Cl. 430/281.1

(57) ABSTRACT

A photocurable relief image printing element is provided. The relief image printing element comprises at least a backing layer and at least one photocurable layer on the backing layer. The photocurable layer comprises at least one binder, at least one ethylenically unsaturated monomer, at least one photoinitiator, and an effective amount of a syndiotactic 1,2-polybutadine. The presence of the syndiotactic 1,2-polybutadiene results in a photocurable layer that exhibits minimal cold flow and good storage stability.

### FIELD OF THE INVENTION

The present invention relates generally to photopolymer printing plates having good storage stability and minimal cold flow.

### BACKGROUND OF THE INVENTION

Flexography is a method of printing that is commonly used for high-volume runs. Flexography is employed for printing on a variety of substrates such as paper, paperboard stock, corrugated board, films, foils and laminates. Newspapers and grocery bags are prominent examples. Coarse surfaces and stretch films can be economically printed only by means of flexography. Flexographic printing plates are relief plates with image elements raised above open areas. Generally, the plate is somewhat soil, and flexible enough to wrap around a printing cylinder, and durable enough to print over a million copies. Such plates offer a number of advantages to the printer, based chiefly on their durability and the ease with which they can be made.

A typical flexographic printing plate as delivered by its manufacturer is a multilayered article made of a backing or support layer; one or more unexposed photocurable layers; a protective layer or slip film; and often a protective cover sheet.

The support sheet or backing layer lends support to the plate. The support sheet, or backing layer, can be formed from a transparent or opaque material such as paper, cellulose film, plastic, or metal. Preferred materials include sheets made from synthetic polymeric materials such as polyesters, polystyrene, polyolefins, polyamides, and the like. The support sheet can optionally comprise an adhesive layer for more secure attachment to the photocurable layer(s). Optionally, an antihalation layer may also be provided between the support layer and the one or more photocurable layers. The antihalation layer is used to minimize halation caused by the scattering of UV light within the non-image areas of the photocurable resin layer.

The photocurable layer(s) are formulated from photocurable materials that comprise any of the known photopolymers, monomers, initiators, reactive or non-reactive diluents, fillers, and dyes. The term “photocurable” refers to a composition which undergoes polymerization, cross-linking, or any other curing or hardening reaction in response to actinic radiation with the result that the unexposed portions of the material can be selectively separated and removed from the exposed (cured) portions to form a three-dimensional or relief pattern of cured material. Preferred photocurable materials include an elastomeric compound, an ethylenically unsaturated compound having at least one terminal ethylene group, and a photoinitiator. Examples of photocurable materials are disclosed in European Patent Application Nos. 0 456 336 A2 and 0 640 878 A1 to Goss, et al., British Patent No. 1,366,769, U.S. Pat. No. 5,223,375 to Berrier, et al., U.S. Pat. No. 3,867,153 to MacLahan, U.S. Pat. No. 4,264,705 to Allen, U.S. Pat. Nos. 4,323,636, 4,323,637, 4,369,246, and 4,423,135 all to Chen, et al., U.S. Pat. No. 3,265,765 to Holden, et al., U.S. Pat. No. 4,320,188 to Heinz, et al., U.S. Pat. No. 4,427,759 to Gruetzmacher, et al., U.S. Pat. No. 4,622,088 to Min, and U.S. Pat. No. 5,135,827 to Bohm, et al., the subject matter of each of which is herein incorporated by reference in its entirety. More than one photocurable layer may also be used.

The photocurable materials generally cross-link (cure) and harden through radical polymerization in at least some actinic wavelength region. As used herein, actinic radiation is radiation capable of polymerizing, cross-linking or curing the photocurable layer or photopolymerizable composition. Actinic radiation includes, for example, amplified (e.g., laser) and non-amplified light, particularly in the UV and violet wavelength regions. One commonly used source of actinic radiation is a mercury are lamp, although other sources are generally known to those skilled in the art.

The slip film is a thin layer, which protects the photopolymer from dust and increases its ease of handling. In a conventional (“analog”) plate making process, the slip film is substantially transparent to UV light. In this process, the printer peels the cover sheet off the printing plate blank, and places a negative on top of the slip film layer. The plate and negative are then subjected to flood-exposure by UV light through the negative. The areas exposed to the light cure, or harden, and the unexposed areas are removed (developed) to create the relief image on the printing plate. Instead of a slip film, a matte layer may also be used to improve the ease of plate handling. The matte layer typically comprises fine particles (silica or similar) initially suspended in an aqueous binder solution. The matte layer is coated onto the photopolymer layer and then allowed to air dry. A negative is then placed on the matte layer for subsequent UV-flood exposure of the photocurable layer.

In a “digital” or “direct to plate” plate making process, a laser is guided by an image stored in an electronic data file, and is used to create an in situ negative in a digital (i.e., laser ablatable) masking layer, which is generally a slip film which has been modified to include a radiation opaque material. Portions of the laser ablatable layer are ablated by exposing the masking layer to laser radiation at a selected wavelength and power of the laser. Examples of laser ablatable layers are disclosed for example, in U.S. Pat. No. 5,925,500 to Yang, et al., and U.S. Pat. Nos. 5,262,275 and 6,238,837 to Fan, the subject matter of each of which is herein incorporated by reference in its entirety.

After imaging, the photosensitive printing element is developed to remove the unpolymerized portions of the layer of photocurable material and reveal the crosslinked relief image in the cured photosensitive printing element. Typical methods of development include washing with various solvents or water, often with a brush. Other possibilities for development include the use of an air knife or heat plus a blotter. The resulting surface has a relief pattern that reproduces the image to be printed. The relief pattern typically comprises a plurality of dots, and the shape of the dots and the depth of the relief, among other factors, affect the quality of the printed image. After the relief image is developed, the relief image printing element may be mounted on a press and printing commenced.

Flexographic printing elements can be made from these photocurable materials by solvent casting or by extruding, calendering or pressing at an elevated temperature of the photocurable material into the form of a layer or self-supporting sheet on a suitable casting wheel, belt or platen.

Extrusion is a preferred method for making photocurable relief image printing elements and thus it is important that the photocurable material extrudes well. It is equally important that the photocurable material should have good storage stability with minimal cold flow.

Cold flow refers to the distortion, deformation, or dimensional change which takes place in materials under continuous load at temperatures within the working range. Cold flow deleteriously affects storage stability of the material in that an excessive amount of cold flow results in the photocurable material becoming unacceptable, edge fusion occurs which prevents unstacking of photopolymerizable plates without damaging the continuity of the photopolymerizable composition.

Storability with minimization of cold flow can be imparted by proper selection and formulation of the components of the photopolymerizable material. For example, U.S. Pat. No. 5,075,192 to Fryd et al., the subject matter of which is herein incorporated by reference in its entirety, describes the use of microgels in the photosensitive resin composition to control cold flow.

Other means of controlling cold flow include using an on- or off-line back exposure step employing actinic radiation. However, this involves an additional process and variable. In addition, this technique is directional in that the floor is built on the side where the on-line back exposure is applied. Due to this reason, the backing layer must be transparent and based thereon, biaxially oriented heat set polyethylene terephthalate films are most commonly used as backing layers so that actinic radiation passes through the backing layer. However, this imposes a limitation on the types of backing layers that can be used.

Thus, it would be desirable to develop an improved photocurable printing element with minimal cold flow while allowing for the use of various types of backing layers.

### SUMMARY OF THE INVENTION

It is an object of the present invention to provide a photopolymerizable printing element having at least one photocurable layer that exhibits good storage stability and minimal cold flow.

It is another object of the present invention to tailor the severity of cold flow in uncured photocurable resin compositions.

It is still another object of the present invention to alter the rheological properties of uncured photocurable resin compositions.

To that end, in a preferred embodiment, the present invention relates generally to a photocurable relief image printing element, the photocurable relief image printing element comprising:
a) a backing layer;
b) at least one photocurable layer, said at least one photocurable layer comprising:
   i) at least one binder;
   ii) at least one ethylenically unsaturated monomer;
   iii) at least one photoinitiator; and
   iv) an effective amount of a syndiotactic 1,2-polybutadine, and
c) optionally, a removable coversheet.

wherein the at least one photocurable layer exhibits minimal cold flow and good storage stability.

In another preferred embodiment, the present invention relates generally to a method of producing a photocurable relief image printing element exhibiting minimal cold flow and good storage stability, the method comprising the steps of:
a) preparing a photocurable composition comprising:
   i) at least one binder;
   ii) at least one ethylenically unsaturated monomer;
   iii) at least one photoinitiator; and
   iv) an effective amount of a syndiotactic 1,2-polybutadine, and
b) forming at least one layer of the photocurable composition into a photocurable layer on a backing layer; and

wherein the photocurable printing element exhibits minimal cold flow and has good storage stability.

### BRIEF DESCRIPTION OF THE DRAWINGS

For a fuller understanding of the invention, reference is had to the following description taken in connection with the accompanying figures, in which:

FIG. 1 depicts a graph of zero-shear viscosity, content of syndiotactic 1,2-polybutadiene and floor built of various photoresins. The zero-shear viscosity was determined at 40° C. The floor built as depicted in FIG. 1 includes a 5 mil polyethylene terephthalate backing film.

FIG. 2 depicts a graph of the response surface of the zero-shear viscosity determined at 40° C. with respect to the content of syndiotactic 1,2-polybutadiene in various photoresins. A transformation was made for this statistical analysis (α=0.05) on the zero-shear viscosity by common (base 10)Log, the scale utilized in FIG. 1.

FIG. 3 depicts a graph of the surface response of the floor built with respect to the content of syndiotactic 1,2-polybutadiene in various photoresins. The statistical analysis (α=0.05) was conducted using the floor built which includes the 5 mil polyethylene terephthalate backing film, as shown in FIG. 1 and in Table 1.

### DETAILED DESCRIPTION OF THE PREFERRED EMBODIMENTS

The present invention relates generally to photocurable materials for use in producing flexographic relief image printing elements which exhibit good storage stability and minimal cold flow. The present invention tailors the severity of cold flow of photocurable resin compositions by altering rheological properties of the composition. In a preferred embodiment, the rheological properties of the composition are altered by including in the photocurable resin composition a syndiotactic 1,2-polybutadiene which induces a partially cured entity within a given photoresin.

The syndiotactic 1,2-polybutadiene content determines the extent of the partially cured entity which directly governs the rheological properties of the photocurable material. In a preferred embodiment, the syndiotactic 1,2-polybutadiene usable in the present invention is a low molecular weight, low crystallinity syndiotactic 1,2-polybutadiene. Suitable syndiotactic 1,2-polybutadienes are available from Japan Synthetic Rubber under the Tradenames RB810, RB820, RB830 and RB840. Other syndiotactic 1,2-polybutadienes exhibiting similar properties would also be usable in the practice of the present invention.

As described in detail herein, cold flow behavior is governed by the rheological properties of a given resin as modified by the syndiotactic 1,2-polybutadiene content of the resin. Therefore, no additional treatment is necessary to build sufficient floor to prevent severe cold flow and the present invention can be utilized with any plate gauge or hacking material.

The present invention relates generally to a process of making a photocurable relief image printing element having an in situ non-directional floor layer that is formed during the exposure step that uses an effective amount of a syndiotactic 1,2-polybutadiene to control cold flow in the photocurable composition.

In a preferred embodiment, the present invention relates generally to a photocurable relief image printing element comprising:
a) a backing layer;
b) at least one photocurable layer, said photocurable layer comprising:
   i) at least one hinder;
   ii) at least one ethylenically unsaturated monomer;
   iii) at least one photoinitiator; and
   iv) an effective amount of a syndiotactic 1,2-polybutadine, and
c) optionally, a removable coversheet.
wherein the photocurable layer exhibits minimal cold flow and has good storage stability.

The photocurable material for use in fabricating the flexographic printing element typically comprises binder(s), monomer(s) and photoinitiator(s).

The binder preferably comprises an A-B-A type block copolymer where A represents a non-elastomeric block, preferably a vinyl polymer, more preferably polystyrene, and B represents an elastomeric block, preferably polybutadiene or polyisoprene. Preferably, the non-elastomer to elastomer ratio is in the range of from 10:90 to 35:65. In a preferred embodiment, the binder is a styrene-isoprene-styrene block copolymer. One suitable styrene-isoprene-styrene block copolymer is available from Kraton Polymers, LLC under the tradename Kraton D1161. Other binders, including other similar styrene-isoprene-styrene block copolymers, are also usable in compositions of the invention.

The photocurable material also comprises at least one ethylenically unsaturated monomer. Suitable monomers include, for example, multifunctional acrylates, multifunctional methacrylates and polyacryloyl oligomers. Examples of suitable monomers include one or more of ethylene glycol diacrylate, hexanediol diacrylate, diethylene glycol diacrylate, glycerol diacrylate, trimethylol propane triacrylate, hexane diol dimethacrylate, glycerol triacrylate, trimethylolpropane triacrylate, ethylene glycol dimethacrylate, 1,3-propanediol dimethacrylate, 1,2,4-butanetriol trimethacrylate, 1,4-butanediol diacrylate, and combinations of one or more of the foregoing. In a preferred embodiment, the ethylenically unsaturated monomer comprises trimethylol propane triacrylate.

The photocurable material should also have at least one photoinitiator. Any of the known classes of photoinitiators, particularly free radical photoinitiators such as quinones, benzophenones, benzoin ethers, aryl ketones, peroxides, biimidazoles, diacyliodoniums, triacylsulfoniums, phosphoniums, and diazoniums are usable in the practice of the invention.

In addition to the binder, monomer, and photoinitiator, the photocurable composition may also comprise other additives known in the art such as plasticizers, anti-oxidants, oxygen scavengers, flow modifiers, colorants, and fillers, by way of example and not limitation.

Longer front exposure times are typically required for the transfer of fine detail images onto the photocurable element due to the presence of oxygen in DTP technology. Thus, it is preferable to include, for example, oxygen scavengers into the photocurable material to counter the effects of the oxygen, thereby decreasing the exposure time (i.e., increasing the photospeed of the photopolymer).

If used, the oxygen scavenger is preferably a phosphine compound. Representative phosphine compounds include triphenylphosphine, tri-p-tolylphosphine, diphenylmethyiphosphine, diphenylkethylphosphine, diphenylpropylphosphine, dimethylphenylphosphine, diethylphenylphosphine, dipropylphenylphosphine, divinylphenylphosphine, divinyl-p-methoxyphenylphosphine, divinyl-p-bromophenylphosphine, divinyl-p-tolylphosphine, diallyphenylphosphine, methoxyphenylphosphine, diallyl-p-bromophenylphosphine and diallyl-p-tolylphosphine. In a preferred embodiment, the oxygen scavenger comprises triphenyiphosphine.

On top of the layer of photocurable material is optionally, but preferably, a masking layer, which allows for the selective polymerization of the layer of photocurable material. Thus, the masking layer must be made to be removed or become transparent to actinic radiation in areas where the layer of photocurable material is to be polymerized, but at the same time block actinic radiation in areas where the layer of photocurable material is to remain unpolymerized and developed away to create the relief image necessary for flexographic printing.

Preferably, the masking layer is selectively ablatable using laser radiation in the pattern of the desired image. In the case of laser ablation, the masking layer generally comprises an ultraviolet radiation absorbing material, an infrared radiation absorbing material and a binder. Dark inorganic pigments such as carbon black or graphite can function as both the ultraviolet radiation absorbing material and infrared radiation absorbing material. Suitable binders include polyamides and cellulosic polymers. Suitable masking layers are described in U.S. Pat. Nos. 6,605,410 to Yang and 6,238,837 an 5,262,275, both to Fan, the teachings each of which are incorporated herein by reference in their entirety.

In the alternative a negative on top of the photocurable material or slip film layer (if used). The plate and negative are then subjected to flood-exposure by UV light through the negative.

The viscosity at the limit of low shear rate is defined as zero shear viscosity (ηₒ). In essence, the viscosity a product will ultimately attain when at rest and undisturbed. The zero shear viscosity is expressed as:

$${η}_{∘ } = {lim}_{γ -> 0} η ( γ ) , \\ η ( γ ) = \frac{σ}{γ} ,$$

wherein η(γ) is the viscosity, γ is the shear rate and is the shear stress. Practically, ηₒ is the viscosity a photoresin will attain at rest and undisturbed at a given temperature. This implies that if the temperature is reasonably low, such as in the range of about 40° C., ηₒ should reflect fairly precisely the cold flow. In other words, ηₒ at 40° C. can be a good measure of the cold flow in a way that the higher the ηₒ, the lower the cold flow, and vice versa.

As described herein, photoresins containing an effective amount of syndiotactic 1,2-polybutadiene demonstrate good zero shear viscosity and thus good storage stability.

In a preferred embodiment, the syndiotactic 1,2-polybutadiene has an average molecular weight of between about 10,000 and about 300,000, more preferably an average molecular weight of between about 100,000 and about 140,000. In addition, the syndiotactic 1,2-polybutadiene preferably has a 1,2-unit content of about 80 to about 100 percent and a crystallinity of between about 10 and about 30 percent. The syndiotactic 1,2-polybutadiene also preferably has a melting point of between about 65 to about 130° C.

In a preferred embodiment, the syndiotactic 1,2-polybutadiene is present in the photocurable layer at a concentration of between about 2 and about 15 percent by weight, more preferably between about 4 and about 10 percent by weight.

As well, a value of zero shear viscosity of the at least one photocurable layer made in accordance with the process described herein is greater than about 800,000 (Pa-sec)², more preferably, greater than about 1,500,000 Pa-sec.

### EXAMPLES

Various photoresin formulations were prepared as follows:

TABLE 1
Photoresin compositions comprising syndiotactic 1,2-polybutadiene

| Composition | 1158 | 1160 | 1161 | 1162 | 1167 | 1168 | 1169 |
|---|---|---|---|---|---|---|---|
| Binder | 59.28 | 51.87 | 51.87 | 51.87 | 51.87 | 55.26 | 55.62 |
| Syndiotactic 1,2- | 0.00 | 7.41 | 7.41 | 7.41 | 10.00 | 4.00 | 7.95 |
| polybutadiene | | | | | | | |
| (RB 820) | | | | | | | |
| Plasticizer (PB-1000) | 12.50 | 12.50 | 12.50 | 12.50 | 9.89 | 12.50 | 20.44 |
| TMPTA | 2.44 | 2.44 | 2.44 | 2.44 | 2.44 | 2.44 | 3.00 |
| CN 307 | 3.66 | 3.66 | 3.66 | 3.66 | 3.66 | 3.66 | 0.00 |
| HDDA | 19.14 | 19.14 | 15.14 | 15.14 | 19.14 | 19.14 | 10.00 |
| Photoinitiator (TPO) | 2.16 | 2.16 | 2.16 | 2.16 | 2.16 | 2.16 | 2.16 |
| Anti-oxidant (BHT) | 0.83 | 0.83 | 0.83 | 0.83 | 0.83 | 0.83 | 0.83 |
| Ricaryl 3500 | | | 4.00 | | | | |
| CN 2302 | | | | 1.00 | | | |

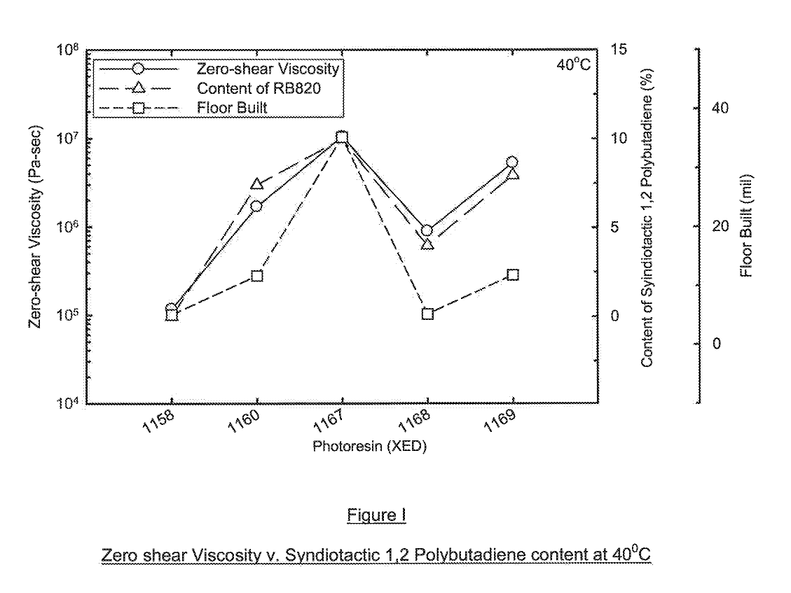

Table 2 summarizes the content of syndiotactic 1,2-polybutadiene, the floor built and ηₒ at 40° C. for various resins, which are collectively plotted in FIG. 1.

TABLE 2
The content of syndiotactic 1,2-polybutadiene, zero shear viscosity
and floor built of various XED photoresins

| XED formula | 1158 | 1160 | 1167 | 1168 | 1169 |
|---|---|---|---|---|---|
| % | 0.00 | 7.41 | 10.00 | 4.00 | 7.95 |
| Floor built | 5.08 | 11.7 | 35.2 | 5.18 | 11.82 |
| (mil)¹ | | | | | |
| Zero shear | 117,378 | 1,696,684 | 10,458,919 | 893,319 | 5,280,238 |
| viscosity | | | | | |
| (Pa-sec) | | | | | |

¹The numbers shown include the 5 mil polyethylene terephthalate backing film. Thus, the floor built for XED 1158 and 1168 is essentially zero
²The zero shear viscosity was determined at 40° C.

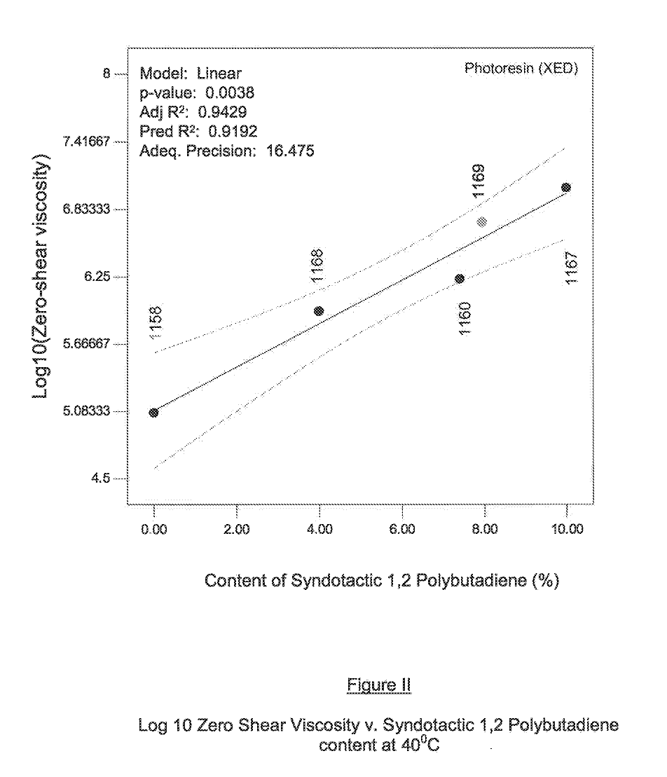

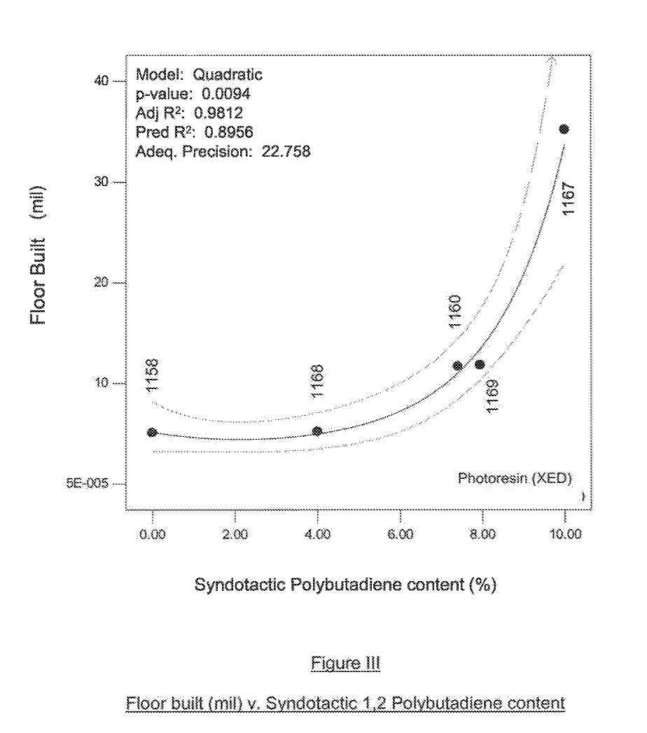

As is clearly seen from Table 2, there is an irrefutable resemblance among them—both ηₒ and the floor built increase as the content of syndiotactic 1,2-polybutadiene increases and vice versa. To quantify this similarity, statistical analyses were conducted on both ηₒ and the floor built with respect to the syndiotactic 1,2-polybutadiene content and their response surfaces were constructed, which are displayed in FIGS. 2 and 3 respectively. A linear model explains the behavior of ηₒ while a quadratic model accounts for the same of the floor built. Based on the parameters obtained from each model such as the low p-value, the good agreement between adjusted and predicted R², and high precision, the models suggested both ηₒ and the floor built are statistically very sound.

The most noticeable fact observed in FIGS. 1 and 2 and Table 2 is that ηₒ increases dramatically with increasing a relatively small amount of syndiotactic 1,2-polybutadiene content. More specifically, ηₒ increases by roughly two orders of magnitude as the syndiotactic 1,2-polybutadiene content increases by 10%. This clearly demonstrates the remarkable efficiency of syndiotactic 1,2-polybutadiene in hindering cold flow, which can beneficially be utilized to tailor the severity of the issue that inherently occurs in uncured photoresins.

For the sake of discussion, it is worth considering both chemical and mechanical aspects that increase vulnerability to cold flow. From a chemical perspective, monomers are known to be a prime contributor to the issue. In fact, the photoresins examined herein contain a large amount of monomer (approximately 21%), with the exception of XED 1169 (approximately 13% of monomers, but about 10% more plasticizer than the others). Therefore, it is highly expected that XED 1158 would suffer from a significant cold flow issue, based on its low zero-shear viscosity of 117,378 Pa-sec at 40° C. (Table 2 and FIG. 1). This in turn can simply be remedied by introducing the syndiotactic 1,2-polybutadiene to the system. From a mechanical perspective, the susceptibility to cold flow becomes higher as the plate gauge increases. Therefore, thick-gauged plates such as corrugated plates that typically offer low hardness tend to be more vulnerable than thin-gauged ones to cold flow. A conventional method to minimize the cold flow is to build a sufficient floor via on-line back exposure during the plate manufacturing unless a given photoresin is particularly engineered to that end. In contrast, in the present invention, it can be shown that the dependency of ηₒ on the syndiotactic 1,2-polybutadiene content can be used to formulate photoresins particularly suited for an inherently robust corrugated plate with minimal cold flow.

The correlation of storage stability and, particularly, lack of substantial cold flow of the photosensitive composition causing edge fusion can be measured by a creep viscosity test. A storage stable composition will have a creep viscosity of at least 5,000,000 Pa-Sec preferably at least 6,000,000 Pa-Sec, and most preferably at least 7,000,000 Pa-Sec at 40° C.

In another preferred embodiment, the present invention relates generally to a method of producing a photocurable relief image printing element exhibiting minimal cold flow and good storage stability, the method comprising the steps of:
a) preparing a photocurable composition comprising:
   i) at least one binder;
   ii) at least one ethylenically unsaturated monomer;
   iii) at least one photoinitiator; and
   iv) an effective amount of a syndiotactic 1,2-polybutadine, and
b) forming at least one layer of the photocurable composition into a photocurable layer on a backing layer;

It is also to be understood that the following claims are intended to cover all of the generic and specific features of the invention described herein and all statements of the scope of the invention which as a matter of language might fall therebetween.

What is claimed is:

1. A photocurable relief image printing element, the photocurable relief image printing element comprising:
a) a backing layer;
b) at least one photocurable layer, said at least one photocurable layer comprising:
i) at least one binder;
ii) at least one ethylenically unsaturated monomer;
iii) at least one photoinitiator; and
iv) an effective amount of a syndiotactic 1,2-polybutadine, and
c) optionally, a removable coversheet.

2. The photocurable relief image printing element according to claim 1, wherein the syndiotactic 1,2-polybutadiene has an average molecular weight of between about 10,000 and about 140,000.

3. The photocurable relief image printing element according to claim 2, wherein the syndiotactic 1,2-polybutadiene has an average molecular weight of between about 10,000 and about 140,000.

4. The photocurable relief image printing element according to claim 1, wherein the syndiotactic 1,2-polybutadiene has a 1,2-unit content of about 80 to about 100 percent.

5. The photocurable relief image printing element according to claim 1, wherein the syndiotactic 1,2-polybutadiene has a crystallinity of between about 10 and about 30 percent.

6. The photocurable relief image printing element according to claim 1, wherein the syndiotactic 1,2-polybutadiene has a melting point of between about 65 to about 130° C.

7. The photocurable relief image printing element according to claim 1, wherein the at least one photocurable layer comprises between about 2 and about 15 percent by weight of the syndiotactic 1,2-polybutadiene.

8. The photocurable relief image printing element according to claim 7, wherein the at least one photocurable layer comprises between about 4 and about 10 percent by weight of the syndiotactic 1,2-polybutadiene.

9. The photocurable relief image printing element according to claim 1, wherein the at least one photocurable layer comprises additives selected from the group consisting of plasticizers, oxygen inhibitors, anti-oxidants, oxygen scavengers, flow modifiers, colorants, fillers and combinations of one or more of the foregoing.

10. The photocurable relief image printing element according to claim 1, wherein a value of zero shear viscosity of the at least one photocurable layer is greater than about 800,000 Pa-sec.

11. The photocurable relief image printing element according to claim 10, wherein the value of zero shear viscosity of the at least one photocurable layer is greater than about 1,500,000 Pa-sec.

12. The photocurable relief image printing element according to claim 1, wherein a value of creep viscosity at 40° C. is at least 5,000,000 Pa-Sec.

13. The photocurable relief image printing element according to claim 12, wherein the value of creep viscosity at 40° C. is at least 7,000,000 Pa-Sec.

14. A method of producing a photocurable relief image printing element exhibiting minimal cold flow and good storage stability, the method comprising the steps of:
a) preparing a photocurable composition comprising:
i) at least one binder;
ii) at least one ethylenically unsaturated monomer;
iii) at least one photoinitiator; and
iv) an effective amount of a syndiotactic 1,2-polybutadine, and
b) forming at least one layer of the photocurable composition into a photocurable layer on a backing layer.

15. The method of producing the photocurable relief image printing element according to claim 14, wherein the syndiotactic 1,2-polybutadiene has an average molecular weight of between about 10,000 and about 300,000.

16. The method of producing the photocurable relief image printing element according to claim 15, wherein the syndiotactic 1,2-polybutadiene has an average molecular weight of between about 100,000 and about 140,000.

17. The method of producing the photocurable relief image printing element according to claim 14, wherein the syndiotactic 1,2-polybutadiene has a 1,2-unit content of about 80 to about 100 percent.

18. The method of producing the photocurable relief image printing element according to claim 14, wherein the syndiotactic 1,2-polybutadiene has a crystallinity of between about 10 and about 30 percent.

19. The method of producing the photocurable relief image printing element according to claim 14, wherein the syndiotactic 1,2-polybutadiene has a melting point of between about 65 to about 130° C.

20. The method of producing the photocurable relief image printing element according to claim 14, wherein the at least one photocurable layer comprises between about 2 and about 15 percent by weight of the syndiotactic 1,2-polybutadiene.

21. The method of producing the photocurable relief image printing element according to claim 20, wherein the at least one photocurable layer comprises between about 4 and about 10 percent by weight of the syndiotactic 1,2-polybutadiene.

22. The method of producing the photocurable relief image printing element according to claim 14, wherein the at least one photocurable layer comprises additives selected from the group consisting of plasticizers, oxygen inhibitors, anti-oxidants, oxygen scavengers, flow modifiers, colorants, fillers and combinations of one or more of the foregoing.

23. The method of producing the photocurable relief image printing element according to claim 14, wherein a value of zero shear viscosity of the at least one photocurable layer is greater than about 800,000 Pa-sec.

24. The method of producing the photocurable relief image printing element according to claim 23, wherein the value of zero shear viscosity of the at least one photocurable layer is greater than about 1,500,000 Pa-sec.

25. The method of producing the photocurable relief image printing element according to claim 14, wherein a value of creep viscosity at 40° C. is at least 5,000,000 Pa-Sec.

26. The method of producing the photocurable relief image printing element according to claim 25, wherein the value of creep viscosity at 40° C. is at least 7,000,000 Pa-Sec.
